(19) United States
(12) Patent Application Publication
(10) Pub. No.: US 2016/0172572 A1
(43) Pub. Date: Jun. 16, 2016

(54) METHOD FOR DEPOSITION OF THERMOELECTRIC MATERIAL

(71) Applicant: O-FLEXX TECHNOLOGIES GMBH, Duisburg (DE)

(72) Inventors: Gerhard SPAN, Wattens (AT); Nikolay IOSAD, Taunusstein (DE)

(21) Appl. No.: 14/903,962

(22) PCT Filed: Jul. 17, 2014
(86) PCT No.: PCT/EP2014/065422

§ 371 Date: Jan. 8, 2016

(30) Foreign Application Priority Data
Aug. 14, 2013 (DE) 10 2013 108 791.4

(51) Int. Cl. H01L 35/34

(52) U.S. Cl. CPC H01L 35/34

(57) ABSTRACT

A method for deposition of thermoelectric material on a substrate includes synthesizing nanoparticles of thermoelectric material and providing the nanoparticles in such a way that the printing operations can be implemented optimally, yet with the possibility of pressureless sintering thereafter. Pressureless sintering leads to dense layers, endowing the material with the mechanical and thermoelectric properties obtained by other methods. To prevent the nanoparticles reacting with one another during printing, they are coated with a molecular layer that prevents their aggregation and so leads to their homogeneous distribution in the ink or that renders the powders non-electroconductive for the purposes of laser printing, allowing them to be electrostatically charged so as to operate as toners. After the printing operation, this molecular layer is removed by a pressureless sintering treatment that confers a highly reactive surface on the particles.

The invention pertains to a method for the deposition of thermoelectric material on a substrate.

### PRIOR ART

Thermoelectric materials are currently being studied primarily with the goal of converting heat to electricity and for the purpose of cooling. Various materials are being used for the development of thermoelectric elements, especially Bi, Bi₂Te₃, Bi₂Se₃, Sb₂Se₃, BiSbTe, BiSbSe, and their alloys; as well as PbS, PbSe, PbTe, AgPbSbTe, Cu₂CdSnSe₄, and SiGe.

Thermoelectric materials can be produced in various ways: colloidal chemical synthesis of micro- and nanoparticles from the individual materials or from a mixture of materials, vacuum processes such as thermal vapor deposition, ion and electronic beam vapor deposition, laser ablation, and electrochemical deposition.

The prior arts described below deal with the production and/or the deposition of thermoelectric materials:

1. WO 2011 022189 A2—Synthesis of Silver, Antimony, and Tin-Doped Bismuth Telluride Nanoparticles and Bulk Bismuth Telluride to Form Bismuth Telluride Composites. Doped bismuth telluride nanoparticles are synthesized with an irregular shape and produced as spheres, powders, or suspensions by the use of the non-aqueous synthesis route.

2. CN 101613814 A—Method for Fast Preparing n-Type Bi₂(SeₓTe₍₁₋ₓ))₃ Thermoelectric Material. The direct deposition of elementary Bi, Se, and Te powder is used to produce Bi₂(SeₓTe₍₁₋ₓ₎)₃ as a thermoelectric material.

3. WO 2009 085089 A1—Fabrication of Nanovoid-Imbedded Bismuth Telluride with Low Dimensional System. Bismuth and tellurium nanocrystallites are precipitated from the solution together with nanovoids and subjected to thermal treatment. The bismuth telluride nanocrystallites are present in the form of quantum dots, quantum wires, or quantum wells.

4. US 2011 117,690 A1—Fabrication of Nanovoid-Imbedded Bismuth Telluride with Low Dimensional System. Bismuth telluride nanoparticles are produced from colloidal solutions by spin-coating, dipping, and casting methods.

5. CN 101200002 A—Preparing Process for p-Type Nanometer BiTe-Based Materials. A colloidal method for the synthesis of BiTe nanoparticles in a solution is described.

6. WO 2010 041146 A2 Nanocomposite Thermoelectric Conversion Material, Thermoelectric Conversion Element Including the Same, and Method of Producing Nanocomposite Thermoelectric Conversion Material. A colloidal synthesis of nanoparticles in solution together with the production of the thermoelectric material from a mixture of various nanoparticles is described.

7. JP 2010 040998 A—Method for Manufacturing Thermoelectric Conversion Module. Ink-jet printing for producing thermoelectric elements is disclosed. No information is given concerning the synthesis of the thermoelectric materials.

For the deposition of thermoelectric material, especially for the production of thermoelectric layers and elements, both inkjet and laser printing methods are used. The thermoelectric properties of the deposited material thus achieved, however, are insufficient. Above all, the achievable electrical conductivity is too low in comparison to other production methods, because, with respect to both inkjet printing and laser printing, the sintering of the applied material cannot be carried out under pressure, for pressure would cause the advantages of the printing method such as speed and flexibility to be lost. Although the use of an electrically conductive binder makes it possible to achieve higher electrical conductivities, the binder changes the thermoelectric and mechanical properties of the deposited thermoelectric material.

After the thermoelectric material has been deposited onto a substrate, a thermal sintering step under pressure is usually carried out by a method such as hot-pressing in a mold, high-pressure sintering, or spark plasma sintering (SPS) to establish the electrical conductivity between adjacent particles of the thermoelectric material. To lower the thermal conductivity of the sintered layers, porous or nonporous nanoparticles which do not form an alloy with the thermoelectric matrix or otherwise react with it can also be added.

Against the background of these prior arts, the invention is based on the goal of creating a method for depositing thermoelectric material onto a substrate by means of a printing process in which the thermoelectric properties of the deposited material are improved, and in which in particular the achievable electrical conductivity is increased.

Overview

A method for depositing thermoelectric material, especially in the form of at least one layer, a film, or a thermoelectric element consisting of colloidal nanoparticles in the form of colloidal solutions or powders is described. The colloidal solutions (colloidal system with a liquid medium) are applied by means of an inkjet printing process, whereas the powder is applied by means of the laser printing process.

The colloidal nanoparticles consist of various materials and comprise but are not limited to Bi₂Te₃, Bi₂Se₃, and their alloys (Bi₄₀Te₆₀₋ₓSeₓ), undoped or doped with Sb (Bi₄₀₋ₓSbₓTe₆₀), Sn, Ag, or other atoms, to achieve an n-doping or p-doping of the deposited material. The colloidal nanoparticles are either spherical, cubic, rod-shaped, wire-like, or in the form of tetrapods.

The above-mentioned colloidal nanoparticles are produced by conducting colloidal chemical processes in aqueous and non-aqueous media; on their surface, the particles have a molecular layer (monolayer) of stabilizing organic or inorganic molecules, which comprise but are not limited to the following compounds: aliphatic thiols, amines, and phosphines. The molecular layer of stabilizing organic or inorganic molecules prevents the above-mentioned colloidal nanoparticles from aggregating and recrystallizing at room temperature and thus stabilizes the colloidal solutions. The powder for the laser printing process is obtained from the colloidal solution by removing the solvent from the colloidal solution, wherein the stabilizing molecular layer of organic or inorganic molecules prevents the nanoparticles in the dry powder from recrystallizing and also suppresses their electrical conductivity. The lack of electrical conductivity in a dry powder of the above-mentioned nanoparticles with a stabilizing monomolecular layer is necessary so that the nanoparticles can become electrostatically charged on the photoreceptor drum.

After the thermoelectric material has been deposited, a thermal treatment (sintering) is carried out to create the conductivity between the nanoparticles in the deposited solid layers. During sintering, the molecular layer of stabilizing molecules is thermally removed from the surface of the nanoparticles; the nanoparticles sinter together and recrystallize, and electricity can now be conducted between the adjacent nanoparticles and across all of the sintered layers.

To lower the thermal conductivity of the deposited thermoelectric material, porous and/or hollow nanoparticles, especially nanospheres of SiO₂, TiO₂, Al₂O₃, glass, or quartz are added to the colloidal solutions for inkjet printing or to the powder for laser printing, so that, after the thermal sintering, these nanoparticles form gaps of low thermal conductivity inside the thermoelectric matrix formed out of the sintered nanoparticles.

### DETAILED DESCRIPTION OF THE INVENTION

The present invention pertains to a method based on laser or inkjet printing for depositing thermoelectric material onto a substrate, especially for the production of thermoelectric films and elements, wherein inks or powders are used which contain nanoparticles consisting of various semiconductor materials prepared by means of colloidal solutions (inkjet printing) or powders (laser jet printing).

The substrates for printing consist of, but are not limited to, glass, quartz, metal, flexible polymer films, and rigid plates of polymer material.

The semiconductors and other materials which are suitable for the production of the nanoparticles include but are not limited to Bi, Bi₂Te₃, Bi₂Se₃, and their alloys, undoped or doped with Sb, Sn, Ag, Se or other atoms; the basic element of the thermoelectric materials consists of nanoparticles of the above-described materials of a size in the range of 1-1,000 nm. The shape of the nanoparticles can vary and is not limited to spheres, rods, cubes, wires, or tetrapods.

The preferred synthesis of BiTe nanoparticles and of the above-described compounds can be carried out by low-temperature or high-temperature reaction between the precursor substances in aqueous or non-aqueous (organic) liquids (solvents). Processes of this type are known in and of themselves and are described, for example, in the following publications:
8. Large-Scale Synthesis and Characterization of the size-Dependent Thermoelectric Properties of Uniformly Sized Bismuth Nanocrystals. Jae Sung Son, Kunsu Park, Mi-Kyung Han, Chanyoung Kang, Sung-Geun Park, Jae-Hee Kim, Woochul Kim, Sung-Jin Kim, and Taeghwan Hyeon. Angew. Chem. Int. Ed. 2001, 50, 1363-1366;
9. Development of bismuth tellurium selenide nanoparticles for thermoelectric applications via a chemical synthetic process. Cham Kim DongHwanKim, YoonSooHan, JongShikChung, SangHaPark, SoonheumPark, Hoyoung Kim. Materials Research Bulletin 46 (2011), P. 407-4121.

The average size, the shape, and the exact chemical composition of the nanoparticles depend on the concentration of the precursor substances, on temperature, and on the duration of the reaction as well as on the presence of additives and growth modifiers. After the above-described nanoparticles are obtained with the desired size, shape, and chemical composition, the reaction stops, and the nanoparticles are separated from the reaction mixture by means of, for example, filtration, precipitation, or centrifugation. They are then washed several times to remove impurities and prepared for the printing process. On their surface, the nanoparticles have a monomolecular layer of stabilizing organic or inorganic molecules, which prevents the particles in the colloidal inks for inkjet printing from aggregating, or, in the case of the dry powders for laser printing, the monomolecular layer prevents the particles from recrystallizing and also suppresses their electrical conductivity.

For inkjet printing, the nanoparticles must be brought into a stable aqueous or organic solution to form a colloidal solution or suspension. To this end, one will select a suitable solvent and/or make appropriate modifications to the surface of the nanoparticles to achieve good solubility. The monomolecular layer of stabilizing molecules prevents the nanoparticles from aggregating in the colloidal inks.

For laser printing, the nanoparticles are dried, and the powder is homogenized to the desired mesh size. The mechanical properties of a powder consisting of nanoparticles can be adjusted by modifying the surface of the nanoparticles prior to the drying step. The monomolecular layer of stabilizing molecules prevents the nanoparticles from recrystallizing at room temperature and suppresses their electrical conductivity, so that the nanoparticles do not become electrostatically charged on the photoreceptor drum.

The inkjet printing process can be carried out by using either standard inkjet printers or plotters or specially designed instruments which make it possible to adjust the printing parameters (volume of the microdrops, injection speed, etc.) separately from each other in a manner adapted to the inkjet pressure of the various colloidal solutions. Inkjet printing can be conducted on rigid (glass, polymers, metals) or flexible (polymers, meals) substrates. As needed, the surface of the substrate can be adapted to improve the adhesion of the nanoparticles and polymers; another possibility is to adjust the wetting properties of the colloidal solution of nanoparticles on the substrate. The substrate may possibly contain structured layers or elements, which have been provided prior to the printing step. The structured and printed layers can form a thermoelectric generator.

After all of the solvent has been evaporated and the solid thermoelectric layers or elements consisting of the above-described nanoparticles have been formed, a thermal sintering and fixation step is carried out by means of a suitable heat treatment such as thermal rolling, IR or UHF heating, laser treatment, or a combination of these.

The monomolecular layer of stabilizing molecules is removed thermally from the surface of the nanoparticles by the sintering so that the nanoparticles can recrystallize and electrical conductivity between the adjacent nanoparticles and across the entire sintered layer is achieved. As needed, additional elements or layers (electrical components, protective coverings, etc.) can be formed on the thermoelectric films or elements by means of a similar inkjet printing method or by some other method.

To lower the thermal conductivity of the porous thermoelectric films, solid or hollow nanospheres of titania, alumina, glass, or quartz are also introduced into the colloidal solutions for inkjet printing, so that, after the heat treatment, the nanospheres form areas with low thermal conductivity within the thermoelectric matrix.

LaserJet printing can be carried out by using either standard laser printers or specially designed instruments, which make it possible to adjust the various printing parameters for laser printing independently of each other (static charging, intensity of the laser beam, printing speed, etc.). The monomolecular layer of stabilizing molecules on the surface of the nanoparticles suppresses their electrical conductivity and allows them to be easily electrostatically charged on the photoreceptor drum. The laser printing can be conducted on rigid (glass, polymers, metals) or flexible (polymers, metals) substrates. As needed, the surface of the substrate can be modified for better adhesion of the nanoparticles. The substrate may possibly contain structured layers or elements necessary to obtain functional electrical or electronic components. After the powder consisting of the above-described nanoparticles has been printed onto the substrate, a thermal sintering step is carried out: thermal rolling, IR or UHF heating, or a combination of these. The monomolecular layer of stabilizing molecules is removed thermally from the surface of the nanoparticles to make it possible for the nanoparticles to recrystallize and to achieve electrical conductivity between the adjacent nanoparticles and across the entire sintered layer. As needed, additional thermoelectric elements or layers (electrical components, protective coverings, etc.) can be formed by means of similar LaserJet methods or other methods on the layers or elements already in place.

To lower the thermal conductivity of the sintered layers even more, the nanoparticles of thermoelectric materials can be used in the form of wire-like or tetrapod-shaped particles in the colloidal inks for inkjet printing or in the powders for LaserJet printing. Thermal sintering at a temperature and for a time adapted to the material ensures that the sintered layers of thermoelectric “nanowires” or branched nanoparticles become nanoporous, which lowers the thermal conductivity.
10. PbTe/PbSe tetrapod-like nanoparticles (or “nanostars”) were synthesized and sintered to produce nanoporous thermoelectric layers (Thermoelectric Properties of Lead Chalcogenide Core-Shell Nanostructures. Marcus Sheele, Niels Oeschler, Igor Veremchuk, Sven-Ole Peters, Alexander Littig, Andreas Kornowski, Christian Klinke, and Horst Weller. ACS Nano DOI: 10.1021/nn2017183).

Layers which have been produced by the processes described can contain impurities such as carbon or oxygen, but this has no effect on the performance of the components.

In the following, the invention is explained in greater detail on the basis of several non-limiting exemplary embodiments:

Example 1 discloses the formation of thermoelectric films consisting of n-type Bi₄₀Te₅₄Se₆ nanoparticles by inkjet printing with the use of an aqueous colloidal solution of Bi₄₀Te₅₄Se₆ nanoparticles. Bi₄₀Te₅₄Se₆ nanoparticles with a diameters of approximately 50-100 nm and with an irregular shape were first synthesized by the colloidal route. 50 mmoles of bismuth nitrate was briefly mixed with 10 mL of distilled water, and 0.1 mmole of EDTA (tetravalent acid of ethylenediamine) was added immediately to adjust the pH of the solution to about 1.6. Then a 6 M solution of NaOH was added to shift the pH of the mixture to 11.5. The mixture was stirred for 4-6 hours, ultimately yielding a clear, transparent solution. In parallel, 0.1 mole of elementary tellurium and 0.02 mole of elementary selenium in the form of powders were mixed with an aqueous solution of sodium borohydride, flushed with argon, and heated to 95° C.; the tellurium was then completely dissolved by vigorous agitation. The bismuth salt solution was quickly transferred to the tellurium solution under vigorous agitation, and the reaction mixture was conducted around a circuit for an additional 30-40 hours. The black precipitate was separated from the reaction mixture by centrifugation, washed several times with distilled water, and dried.

Approximately 100 mg of the dry Bi₄₀Te₅₄Se₆ nanoparticles was mixed with 2 mL of methanol, ethanol, isopropanol, or some other suitable solvent and homogenized in a sealed vessel by means of ultrasound. Then 0.1 mL of dodecanethiol was added to the mixture of nanoparticles and organic solvent to form the monomolecular layer of stabilizing molecules on the particle surface. The colloidal solution of Bi₄₀Te₅₄Se₆ was conducted through a 0.45-μm membrane filter to remove the aggregated nanoparticles. Then the colloidal solution was loaded into the inkjet cartridge, and the thermoelectric elements were printed out onto polyimide film and dried at room temperature under a vent hood. The dried layers or elements containing Bi₄₀Te₅₄Se₆ nanoparticles were thermally sintered by rolling at 200-250° C. for 1-60 minutes. The monomolecular layer of dodecanethiol is thermally removed from the surface of the nanoparticles to allow the sintering and recrystallization of the particles and to produce electrical conductivity between the adjacent nanoparticles and across the entire sintered layer.

p-type thermoelectric layers or elements of Bi₁₀Sb₃₀Te₆₀ nanoparticles, which were synthesized by a colloidal route similar to that used for Bi₄₀Te₅₄Se₆ nanoparticles, were produced. 10 mmoles of bismuth nitrate was mixed with 30 mmoles of antimony(III) chloride briefly with 10 mL of distilled water, and 0.1 mmole of EDTA (tetravalent acid of ethylenediamine) was immediately added to adjust the pH of the solution to 1.6. Then a 6 M solution of NaOH was added to shift the pH to 11.5. The mixture was stirred for 4-6 hours to obtain a clear, transparent solution. In parallel, 0.1 mole of elementary tellurium in the form of a powder was mixed with an aqueous solution of sodium borohydride, flushed with argon, and heated to 95° C. under vigorous agitation until the Te was completely dissolved. The solution of bismuth and antimony salts was quickly injected into the tellurium solution and stirred under reflux for 30-40 hours. The black precipitate was separated from the reaction mixture by centrifugation, washed several times with distilled water, and then dried.

Approximately 100 mg of the dry Bi₁₀Sb₃₀Te₆₀ nanoparticles was mixed with 2 mL of methanol, ethanol, isopropanol, or some other suitable solvent and homogenized in a sealed vessel by means of ultrasound. Then 0.1 mL of dodecanethiol was added to the mixture of nanoparticles and organic solvent to form the monomolecular layer of stabilizing molecules on the particle surface. The colloidal solution of Bi₁₀Sb₃₀Te₆₀ was conducted through a 0.45-μm membrane filter to remove the aggregated nanoparticles. The colloidal solution was then loaded into the inkjet cartridge, and the thermoelectric elements were printed out onto polyimide film and dried at room temperature under a vent hood. The dried layers or elements containing Bi₁₀Sb₃₀Te₆₀ were thermally sintered by rolling at 200-250° C. for 1-60 minutes. The monomolecular layer of dodecanethiol is thermally removed from the surface of the nanoparticles to make it possible for the particles to sinter and recrystallize and to produce electrical conductivity between the adjacent particles and across the entire sintered layer. Example 2 demonstrates the formation of thermoelectric layers of n-type Bi₄₀Te₅₄Se₆ nanoparticles by means of LaserJet printing with the use of the aqueous colloidal solution of Bi₄₀Te₅₄Se₆ nanoparticles.

Bi₄₀Te₅₄Se₆ nanoparticles with a diameters of approximately 50-100 nm and with an irregular shape were first synthesized by the colloidal route. 50 mmoles of bismuth nitrate was briefly mixed with 10 mL of distilled water, and 0.1 mmole of EDTA (tetravalent acid of ethylenediamine) was added immediately to adjust the pH of the solution to about 1.6. Then a 6 M solution of NaOH was added to shift the pH of the mixture to 11.5. The mixture was stirred for 4-6 hours, ultimately yielding a clear, transparent solution. In parallel, 0.1 mole of elementary tellurium and 0.02 mole of elementary selenium in the form of powders were mixed with an aqueous solution of sodium borohydride, flushed with argon, and heated to 95° C. The tellurium was completely dissolved by vigorous agitation. The solution of the bismuth salt was quickly added to the tellurium solution under vigorous agitation, and the reaction mixture was conducted around a circuit for an additional 30-40 hours. The black precipitate was separated from the reaction mixture by centrifugation, washed several times with distilled water, and dried.

Approximately 10 g of the dry Bi₄₀Te₅₄Se₆ nanoparticles was mixed with 200 mL of methanol, ethanol, isopropanol, or some other suitable solvent and homogenized in a sealed vessel by means of ultrasound. Then 0.1 mL of dodecanethiol was added to the mixture of nanoparticles and organic solvent to form the monomolecular layer of stabilizing molecules on the particle surface. The colloidal solution of B₁₀Te₃₀Se₆₀ was conducted through a 0.45-μm membrane filter to remove the aggregated nanoparticles. The solvent was evaporated from the mixture, which was then dried to a powder consisting of the Bi₄₀Te₅₄Se₆ nanoparticles, which had previously been covered by the monomolecular layer of dodecanethiol. The powder consisting of the nanoparticles was loaded into a toner cartridge, which was loaded into the laser printer, and the powder was then printed out. The printing process is made possible by the electrostatic charging of the Bi₄₀Te₅₄Se₆ nanoparticles provided with a monomolecular surface layer of dodecanethiol, which prevents electricity from being conducted between the adjacent particles in the powder. The dried layers or elements containing the nanoparticles were then thermally sintered by thermal rolling at 200-250° C. for 1-3 minutes. The monomolecular layer of dodecanethiol is removed thermally by pressureless sintering from the surface of the nanoparticles to allow the nanoparticles to recrystallize and to produce electrical conductivity between the adjacent nanoparticles and across the entire layer.

p-type thermoelectric layers or elements of Bi₁₀Sb₃₀Te₆₀ nanoparticles, which were synthesized by a colloidal route similar to that used for Bi₄₀Te₅₄Se₆ nanoparticles, were produced. 10 mmoles of bismuth nitrate was mixed with 30 mmoles of antimony(III) chloride briefly mixed with 10 mL of distilled water, and 0.1 mmole of EDTA (tetravalent acid of ethylenediamine) was added immediately to adjust the pH of the solution to 1.6. Then a 6 M solution of NaOH was added to shift the pH to 11.5. The mixture was stirred for 4-6 hours to obtain a clear, transparent solution. In parallel, 0.1 mole of elementary tellurium in the form of a powder was mixed with an aqueous solution of sodium borohydride, flushed with argon, and heated at 95° C. under vigorous agitation until all of the Te was dissolved. The solution of bismuth and antimony salts was quickly injected into the tellurium solution and stirred under reflux for another 30-40 hours. The black precipitate was separated from the reaction mixture by centrifugation, washed several times with distilled water, and then dried.

Approximately 10 g of the dry Bi₁₀Sb₃₀Te₆₀ nanoparticles was mixed with 200 mL of methanol, ethanol, isopropanol or some other suitable solvent and homogenized in a sealed vessel by means of ultrasound. Then 0.1 mL of dodecanethiol was added to the mixture of nanoparticles and organic solvent to form the monomolecular layer of stabilizing molecules on the particle surface. The colloidal solution of Bi₁₀Sb₃₀Te₆₀ was conducted through a 0.45-μm membrane filter to remove the aggregated nanoparticles. The solvent was evaporated from the mixture, which was then dried to a powder consisting of the Bi₁₀Sb₃₀Te₆₀ nanoparticles, which had previously been covered with the monomolecular layer of dodecanethiol. The powder consisting of the nanoparticles was loaded into a toner cartridge, which was loaded in turn into the laser printer. The powder was then printed out. The printing process is made possible by the electrostatic charging of the Bi₁₀Sb₃₀Te₆₀ nanoparticles provided with the monomolecular surface layer of dodecanethiol, which prevents electricity from being conducted between the adjacent particles in the powder. The dried layer or the elements containing the nanoparticles were thermally sintered by thermal rolling at 200-250° C. for 1-3 minutes. The monomolecular layer of dodecanethiol is removed thermally from the surface of the nanoparticles to allow the particles to recrystallize and to produce electrical conductivity between adjacent particles and across the entire layer.

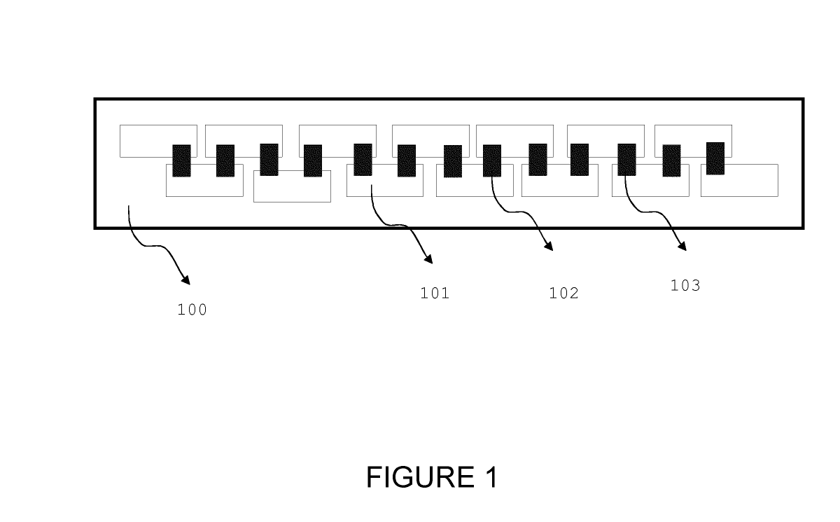

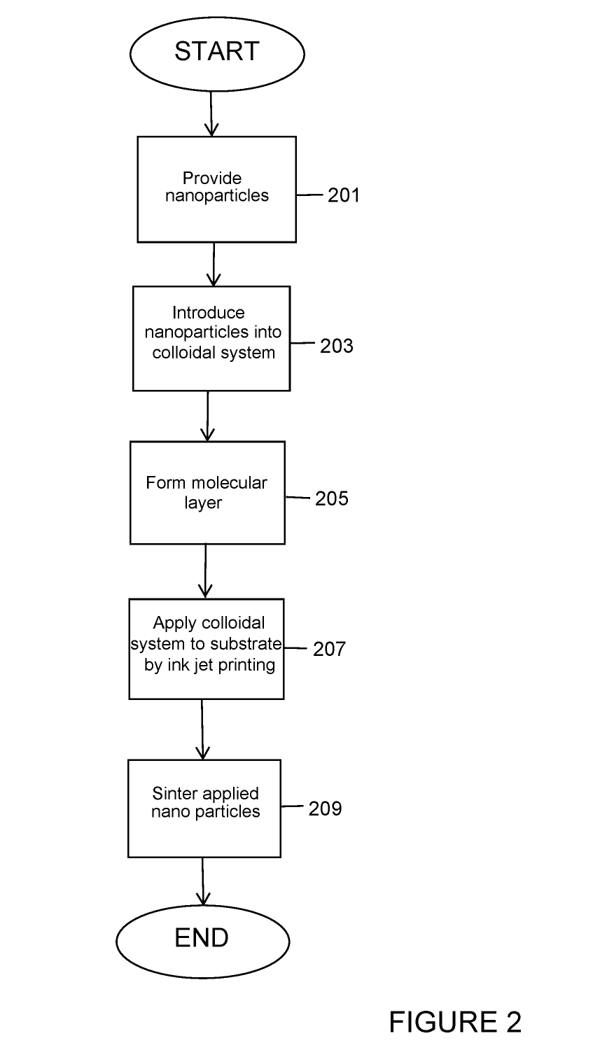

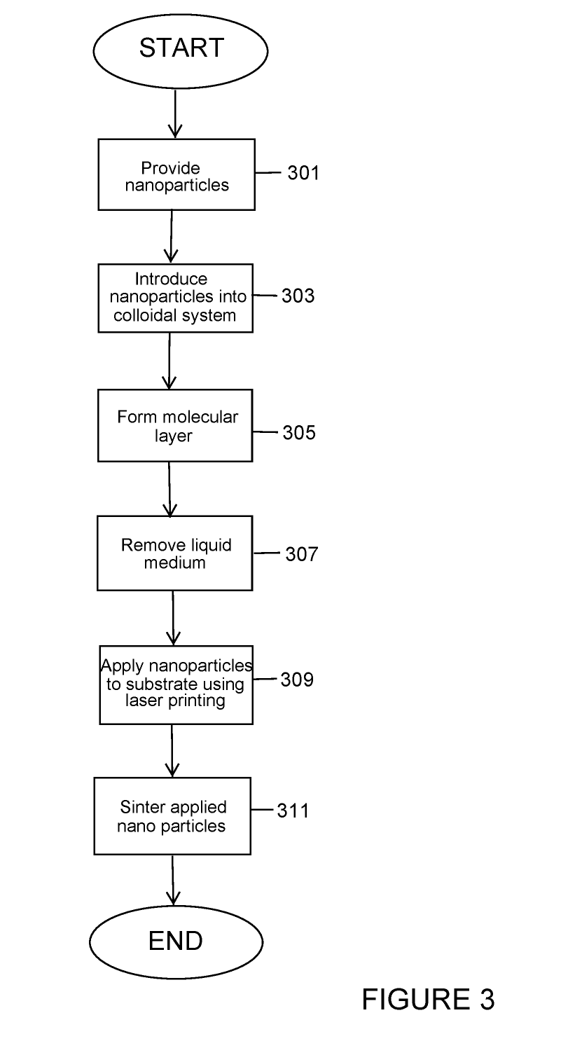

Example 3 pertains to the inkjet printing of components with 2 terminals. The production method is described on the basis of FIG. 1:

1. p-doped thermoelectric materials 102 and n-doped thermoelectric materials 103 are printed by inkjet printing onto a flexible or rigid substrate 100 with copper contacts 101. The copper surfaces can be coated with a layer of Ni (FIG. 1). The substrate material can be any plastic, silicone, glass, or ceramic material with low thermal conductivity such as Kevlar, Kapton, various circuit-board materials such as EP2, 85N, 35N, or composite materials. The copper areas can consist of copper alloys, wherein pure copper is preferred. The ink contains BiTe nanoparticles, which optionally are doped with Se, Sb, or other materials; alternatively, the ink contains SiGe nanoparticles, which optionally are doped with P, As, B. etc.

2. After printing, the p-doped and n-doped thermoelectric materials are sintered. Sintering is carried out by heating or by microwave radiation.

The component functions as follows. The upper row of copper contacts 101 is connected to a heat source, and the lower row of copper contacts is connected to a cooling body. The p-doped and n-doped thermoelectric materials 102/103 are connected in series by the copper contacts (101). A temperature gradient across the thermoelectric materials 102/103 generates an electrical voltage, which increases additively because of the series connection.

Example 4 discloses the formation of thermoelectric films out of n-type Bi₄₀Te₅₄Se₆ nanoparticles with voids by inkjet printing with the use of an aqueous colloidal solution of Bi₄₀Te₅₄Se₆ nanoparticles. Bi₄₀Te₅₄Se₆ nanoparticles with diameters of about 50-100 nm and with an irregular shape were first synthesized by the colloidal method as in example 1. Approximately 100 mg of the dry Bi₄₀Te₅₄Se₆ nanoparticles was mixed with 2 mL of methanol, ethanol, isopropanol, or some other suitable solvent and homogenized in a sealed vessel by means of ultrasound. Then 0.1 mL of dodecanethiol was added to the mixture of nanoparticles and organic solvent to form the monomolecular layer of stabilizing molecules on the particle surface. The colloidal solution of Bi₄₀Te₅₄Se₆ was conducted through a 0.45-μm membrane filter to remove the aggregated nanoparticles. Approximately 10 mg of SiO₂ nanospheres with a diameter of about 20 nm (Aldrich, 637238) was added to this solution, and the solution was homogenized again for 10 minutes with ultrasound. Then the colloidal solution was loaded into the inkjet cartridge, and the thermoelectric elements were printed out onto polyimide film and dried at room temperature under a vent hood. The dried layers of the elements containing the Bi₄₀Te₅₄Se₆ nanoparticles were thermally sintered by rolling at 200-250° C. for 1-60 minutes. The monomolecular layer of dodecanethiol is removed by sintering from the surface of the nanoparticles to allow the nanoparticles to recrystallize and to produce electrical conductivity between the adjacent nanoparticles and across the entire sintered layer. The SiO₂ nanospheres remain unsintered and create voids with low thermal conductivity in the sintered layer.

Example 5 demonstrates the synthesis of Bi₄₀Te₅₄Se₆ nanowires and tetrapods. 1 mmole of bismuth ethyl hexanoate was dissolved in 6 mL of octadecene, to which 200 mg of hexadecylphosphonic acid was then added. The reaction mixture was heated to 160° C. and degassed under vacuum at 10 mbars for 30 minutes. Separately, 1 mmole of elementary Te and 0.1 mmole of selenium were loaded into a reaction tube, which was filled with 2 mL of trioctylphosphine (TOP). The mixture was washed with argon and heated to 250° C. until a clear, orange-yellow solution appeared. The solution of Se and Te in TOP was injected into the solution of the Bi salt in octadecene at 160° C., and this mixture was then also stirred for 5-30 minutes. This method produces Bi₄₀Te₅₄Se₆ nanowires or nanorods of various lengths and diameters. The diameter-to-length ratio depends for the most part on the concentration of hexadecylphosphonic acid and decreases as the concentration of the phosphonic acid increases. To obtain the tetrapod-like Bi₄₀Te₅₄Se₆ nanoparticles, the multiple-injection method was used. First, only 20% of the Se/Te solution in TOP was injected at 160° C., and the reaction mixture was stirred for 5 minutes to promote the formation of spherical seeds. The remainder of the Se/Te solution was injected drop by drop at 160° C. over the course of 5-10 minutes. At the end of the growth phase, the reaction mixture was cooled to 70° C.; the nanoparticles were precipitated with isopropanol, washed several times with isopropanol, and then dried. The dry hydrophobic nanoparticles can be dissolved in toluene and thus result in inks or can be used in the form of powder for laser printing.

Example 6 shows how the electrostatic charging properties of hydrophobic Bi₄₀Te₅₄Se₆ nanoparticles can be modified so that they can be used for laser printing. The hydrophobic nanoparticles (approximately 100 mg), which were produced by means of the method described in example 5, were dissolved in 50 mL of toluene, to which 5 mg of one of various aliphatic thiol alcohols (butanethiol, hexanethiol, decanethiol, dodecanethiol, hexadecanethiol, octadecanethiol) was added. The reaction mixture was stirred at room temperature for 2 hours; the toluene was removed by gentle evaporation; and the solid phase, i.e., the Bi₄₀Te₅₄Se₆ nanoparticles with the monomolecular layer of the corresponding thiol alcohol, was washed several times with isopropanol to remove the excess organic products. Then the solid phase was dried to a powder and used for laser printing. The increased length of the aliphatic thiol alcohol on the surface of the nanoparticles results in stronger electrostatic charging on account of the reduced conductivity between the particles.

In summary, the invention consists in synthesizing and providing the nanoparticles in such a way that the printing process (inkjet and laser printing processes) can be conducted in optimal fashion, whereas the subsequent sintering step can be carried out without pressure. This pressureless sintering leads to dense layers, as a result of which the mechanical and thermoelectric properties of the material reach the values obtained by other methods (in particular by fusion under pressure or sintering under pressure). The nanoparticles thus provided are formed in such a way during synthesis that a large surface-to-volume ratio is obtained and that the particles, because of their shape, interlock with each other in purely mechanical fashion. These properties of the nanoparticles thus provided have the effect that the sintering process leads to effective bonding of all the nanoparticles together even without the application of pressure. So that the nanoparticles do not react with each other during the printing process, the particles are coated with a molecular layer (monolayer), which prevents the particles from aggregating and thus brings about a homogeneous distribution of the particles in the ink (colloidal solution), or, in the case of laser printing, prevents them from becoming electrically conductive, thus making it possible for them to become electrostatically charged and to function effectively as a toner. This molecular layer is removed by the sintering treatment after printing, as a result of which the particles acquire a highly reactive surface. The pressureless sintering leads to good bonds between the nanoparticles among themselves.

1. -14. (canceled)

15. A method for the deposition of thermoelectric material onto a substrate comprising the steps:
providing nanoparticles made of thermoelectric material;
introducing the nanoparticles into a colloidal system comprising a liquid medium;
forming a molecular layer on the surface of the nanoparticles in the colloidal system to prevent the aggregation of the nanoparticles;
applying the colloidal system to the substrate by an inkjet printing process after the step of forming; and
sintering, without pressure, the nanoparticles applied to the substrate such that the molecular layer is removed from the nanoparticles by the sintering and electrical conductivity between the nanoparticles is established.

16. The method according to claim 15, further comprising the step of filtering the colloidal system before the step of applying to remove aggregated nanoparticles.

17. The method according to claim 15, further comprising the step of drying the applied colloidal system before the step of sintering.

18. The method according to claim 15, wherein the step of providing the nanoparticles of thermoelectric material includes providing the nanoparticles using colloidal chemical synthesis.

19. The method according to claim 15, wherein the provided nanoparticles are shaped such that the nanoparticles interlock with each other.

20. The method according to claim 15, wherein the provided nanoparticles are of irregular shape.

21. The method according to claims 15, wherein the provided nanoparticles have a maximum dimension of 1-1,000 nm.

22. The method according to claim 15, wherein the provided nanoparticles are a spherical, cubic, rod-shaped, or wire-shaped, or tetrapod-shaped.

23. The method according to claim 15, further comprising the step of homogenizing the colloidal system before the step of forming.

24. The method according to claim 23, wherein the step of homogenizing is carried out using ultrasound.

25. The method according to claim 15, wherein porous and/or hollow nanoparticles are mixed into the colloidal system.

26. The method according to claim 25, wherein the porous and/or hollow nanoparticles consist of SiO₂, TiO₂, Al₂O₃, glass, or quartz.

27. A method for the deposition of thermoelectric material onto a substrate comprising the steps:
providing dried nanoparticles made of thermoelectric material;
introducing the dried nanoparticles into a colloidal system comprising a liquid medium;
forming a molecular layer on the surface of the nanoparticles in the colloidal system to prevent the aggregation of the nanoparticles;
removing the liquid medium of the colloidal system, so that the nanoparticles provided with the molecular layer are present in the form of a powder;
subsequently applying the nanoparticles present as a powder to the substrate by a laser printing process; and
sintering, without pressure, the applied nanoparticles such that the molecular layer is removed from the nanoparticles by the sintering and electrical conductivity between the nanoparticles is established.

28. The method according to claim 27, further comprising the step of filtering the colloidal system before the step of removing to remove aggregated nanoparticles.

29. The method according to claim 27, wherein the step of providing the nanoparticles of thermoelectric material includes providing the nanoparticles using colloidal chemical synthesis.

30. The method according to claim 27, wherein the provided nanoparticles are shaped such that the nanoparticles interlock with each other.

31. The method according to claim 27, wherein the provided nanoparticles are of irregular shape.

32. The method according to claims 27, wherein the provided nanoparticles have a maximum dimension of 1-1,000 nm.

33. The method according to claim 27, wherein the provided nanoparticles are a spherical, cubic, rod-shaped, or wire-shaped, or tetrapod-shaped.

34. The method according to claim 27, further comprising the step of homogenizing the colloidal system before the step of forming.

35. The method according to claim 34, wherein the step of homogenizing is carried out using ultrasound.

36. The method according to claim 27, wherein porous and/or hollow nanoparticles are mixed into the colloidal system.

37. The method according to claim 36, wherein the porous and/or hollow nanoparticles consist of SiO₂, TiO₂, Al₂O₃, glass, or quartz.

38. A method for the deposition of thermoelectric material onto a substrate comprising the steps:
providing nanoparticles made of thermoelectric material;
introducing the nanoparticles into a colloidal system comprising a liquid medium;
forming a molecular layer on the surface of the nanoparticles in the colloidal system to prevent the aggregation of the nanoparticles;
applying the nanoparticles to the substrate by one of an inkjet printing process and a laser printing process after the step of forming; and
sintering, without pressure, the nanoparticles applied to the substrate such that the molecular layer is removed from the nanoparticles by the sintering and electrical conductivity between the nanoparticles is established.
